(19) United States
(12) Patent Application Publication
(10) Pub. No.: US 2006/0010363 A1
(43) Pub. Date: Jan. 12, 2006

(54) Method and system for correcting low latency errors in read and write non volatile memories, particularly of the flash type

(75) Inventors: Alessia Marelli, Dalmine (BG) (IT); Roberto Ravasio, Ponte San Pietro (IT); Rino Micheloni, Turate (CO) (IT)

Correspondence Address: GRAYBEAL JACKSON HALEY LLP;Bryan A. Santarelli, Suite. 350, 155-108th Avenue N.E., Bellevue, WA, 98004-5973, US

(73) Assignee: STMicroelectronics S.r.l.

(21) Appl. No.: 11/173,896

(22) Filed: Jun. 30, 2005

(30) Foreign Application Priority Data
Jun. 30, 2004 (EP) 04425486.0

(51) Int. Cl. H03M 13/00

(52) U.S. Cl. 714/758

(57) ABSTRACT

A method for correcting errors in multilevel memories, both of the NAND and of the NOR type provides the use of a BCH correction code made parallel by means of a coding and decoding architecture allowing the latency limits of prior art sequential solutions to be overcome. The method provides a processing with a first predetermined parallelism for the coding step, a processing with a second predetermined parallelism for the syndrome calculation and a processing with a third predetermined parallelism for calculating the error position, each parallelism being defined by a respective integer number being independent from the others.

### PRIORITY CLAIM

This application claims priority from European patent application No. 04425486.0, filed Jun. 30, 2004, which is incorporated herein by reference.

### TECHNICAL FIELD

Embodiments of the present invention relates to a method and system for correcting low latency errors in read and write non volatile memories, particularly electronic flash memories.

Embodiments of the invention particularly relates to read and write memories having a NAND structure and the following description is made with reference to this specific field of application for convenience of illustration only, since the invention can be also applied to memories with NOR structure, provided that they are equipped with an error correction system.

Even more particularly, embodiments of the invention relates to a method and system for correcting errors in electronic read and write non volatile memory devices, particularly flash memories, of the type providing at least the use of a BCH binary error correction code for the information data to be stored.

### BACKGROUND

As it is well known in this specific technical field, two-level and multilevel NAND memories have such a Bit Error Rate (BER) as to require an Error Correction system (ECC) in order to allow them to be used as reliably as possible.

Among the innumerable present ECC correction methods a particular interest is assumed by the so-called cyclical correction codes; particularly binary BCH and Reed-Solomon codes.

The main features concerning these two codes are quoted hereafter by way of comparison.

The code will be examined first:

1 ) Binary BCH.

This code operates on a block of binary symbols. If N (4096+128) is the block size, the number of parity bits is P (assuming to correct 4 bits, P is equal to 52 bits).

As it will be seen hereafter, the code operates on a considerably lower number of bits with respect to the Reed-Solomon code.

The canonical coding and decoding structures process the data block by means of sequential. operations on the bits to be coded or decoded.

The latency to code and decode data blocks is higher than the Reed-Solomon code latency since it operates on symbols.

The arithmetic operators (sum, multiplication, inversion) in GF(2), and thus those necessary for this kind of code, are extremely simple (XOR, AND, NOT).

The code corrects K bits.

The other code will now be seen:

2) Reed Solomon

It operates on a block of symbols composed by a plurality of bits.

If N ((4096+128)/9) is the symbol block size, the number of parity symbols is P (assuming to correct 4 errors, P is equal to 8 symbols formed by 9-bit, i.e. 72 bits).

The canonical coding and decoding structures process the data block by means of sequential operations on the symbols to be coded or decoded.

In this case, the latency to code and decode data blocks is lower than the BCH binary code latency since it operates on symbols rather than bits (1/9).

Another difference is due to the fact that the arithmetic operators (sum, multiplication, inversion) in GF(2^{m}) are in this case complex operators with respect to the BCH code.

The code corrects K symbols. This is very useful in communication systems such as: Hard disks, Tape Recorders, CD-ROMs etc. wherein sequential errors are very probable. This latter feature, however, often cannot be fully used in NAND memories.

For a better understanding of aspects of the present invention, the structure of the error correction systems using a BCH coding and decoding will be analyzed hereafter, the structure of Reed Solomon correction systems will be analyzed afterwards.

The BCH Structure

The typical structure of a BCH code is shown in the attached FIG. 1 wherein the block indicated with C represents the coding step while the other blocks 1, 2 and 3 are active during the decoding and they refer to the syndrome calculation, to the error detection polynomial calculation (for example by means of the known Berlekamp-Massey algorithm) and to the error detection, respectively. The block M indicates a storage and/or transfer medium of the coded data.

Blocks C, 1 and 3 can be realized by means of known structures, (for example according to what has been described by: Shu Lin, Daniel Costello—“Error Control Coding: Fundamentals and Applications”) operating in a serial way and thus having a latency being proportional to the length of the message to be stored.

In particular:

BLOCK C: the block latency is equal to the message to be stored (4096 bits);

BLOCK 1: the block latency is equal to the coded message (for a four-error-corrector code 4096+52);

BLOCK 3: the block latency is equal to the coded message (for a four-error-corrector code 4096+52).

FIG. 2 shows the flow that the data being written and read by a memory must follow in order to be coded and decoded by means of a BCH coding system. Bits traditionally arrive to the coder of the block C in groups of eight, while the traditional BCH coder processes one bit at a time. Similarly, bits are traditionally stored and read in groups of eight, while the traditional BCH decoder (1 and 3) processes them in a serial way.

Blocks (2.1) grouping or decomposing the bits to satisfy said requirements are thus required in the architecture.

Consequently, in order not to slow the data flow down, it is required that the coder and the decoder operate with a clock time being eight times higher than the clock of the data storage and reading step.

The other correction mode of the Reed Solomon type will now be examined.

The Reed Solomon Structure (RS)

Reed-Solomon codes do not operate on bits but on symbols. As shown in FIG. 3, the code word is composed of N symbols. In the example each symbol is composed of 4 bits. The information field is composed of K symbols while the remaining N-K symbols are used as parity symbols.

The coding block C and the syndrome calculation block 1 are similar to the ones used for BCH codes with the only difference that they operate on symbols. The error detector block 3 must determine, besides the error position, also the correction symbol to be applied to the wrong symbol.

Since the code RS operates on symbols, a clearly lower latency is obtained paying a higher hardware complexity due to the fact that operators are no more binary.

BLOCK C: the block latency is equal to the number of symbols in the message to be coded (462);

BLOCK 1: the block latency is equal to the number of symbols in the coded message (470);

BLOCK 3: the block latency is equal to the number of symbols in the coded message (470).

Also in this case the same conditions about the bit grouping and decomposition occur. This time however the Reed-Solomon code does not operate in a sequential way on bits but on s-bit symbols.

Also in this case structures for grouping bits are required, but to ensure a continuous data flow the clock time must be 8/s. It must be observed that in the case s=8 these architectures are not required.

In this way the latency problem is solved, but, by comparing the number of parity bits required by BCH and Reed-Solomon, it can be seen that Reed-Solomon is much more expensive.

In the case being considered by way of example, i.e., 4224 (4096+128) data bits for correcting four errors, Reed-Solomon codes require twenty parity bits more than BCH binary codes.

Although advantageous under several aspects, known systems do not allow the latency due to the sequential bit processing to be reduced by keeping a number of parity bits, close to the theoretical minimum.

In substance, the advantages of the code RS low latency are accompanied by a high demand of parity bits and a higher system structural complexity.

### SUMMARY

An embodiment of the invention is directed to an error correction method and system having respective functional and structural features such as to allow the coding and decoding burdens to be reduced, reducing both the latency and the system structural complexity, thus overcoming the drawbacks of the solutions provided by the prior art.

The error correction method and system obtain for each coding and decoding block a good compromise between the speed and the occupied circuit area by applying a BCH code of the parallel type requiring a low number of parity bits and having a low latency.

By using this circuit solution it is possible to use for each coding and decoding block the most convenient parallelism and thus latency degree, taken into account that, in the flash memory, the coding block is only involved in writing operations (only once since it is a non volatile memory), the first decoding block is involved in all reading operations (and it is the block requiring the greatest parallelism), while correction blocks are only called on in case of error and thus not very often.

In this way it is often possible to optimize the system speed reducing in the meantime the circuit area occupied by the memory device.

### BRIEF DESCRIPTION OF THE DRAWINGS

Features and advantages of the methods and systems according to the invention will be apparent from the following description of an embodiment thereof given by way of indicative and non limiting example with reference to the attached drawings.

FIG. 1 is a schematic block view of a BCH coding and decoding system.

FIG. 2 is a schematic block view of the system of FIG. 1 emphasizing some blocks being responsible for grouping and decomposing bits.

FIG. 3 shows how the Reed-Solomon code, coding symbols rather than coding bits, operates.

FIG. 4 shows how the parity calculation block operates for a traditional BCH code.

FIG. 5 is a schematic view of a base block for calculating the parity in the case of the first parallelization type.

FIG. 6 shows the block being responsible for calculating the parity as taught by the first parallelization method for a particular case.

FIG. 8 is a schematic view of the block being responsible for searching the roots of the error detector polynomial through the Chien method by using a traditional BCH code.

FIG. 9 specifies what the test required by the Chien algorithm means, particularly what summing the content of all the registers and the constant 1 involves.

FIG. 10 shows what multiplying the content of a register by a power of a as required by the Chien algorithm involves.

FIG. 11 is a schematic view of the architecture of an algorithm for searching the roots of an error detector polynomial in the case of a parallel BCH coding according to the first parallelization method.

FIG. 12 specifies FIG. 11 in greater detail, i.e. it shows for which powers of α it is necessary to multiply the register content in the case of the first by-four parallelization.

FIG. 13 is a schematic view of a base block for calculating the parity according to the traditional BCH method.

FIG. 14 is a schematic view of a circuit being responsible for calculating in parallel the parity according to the second method and by parallelizing twice.

FIG. 15 is a schematic view of a circuit for calculating the parity by parallelizing q times according to the second method.

FIG. 16 is a schematic view of a circuit block being responsible for calculating the “syndrome” of a BCH binary code.

FIG. 17 is a schematic view of a circuit block being responsible for calculating the “syndrome” for a parallelized code according to the second method of the present invention.

FIG. 18 is a schematic view of the architecture of an algorithm for searching the roots of an error detector polynomial in the case of a known serial BCH code.

FIG. 19 is a schematic view of the architecture of an algorithm for searching the roots of an error detector polynomial in the case of a parallel BCH coding according to the second method of the present invention.

FIG. 20 is a schematic block view of the system of a further embodiment of the error correction system according to the invention, emphasizing some blocks being responsible for grouping and decomposing bits in parallel.

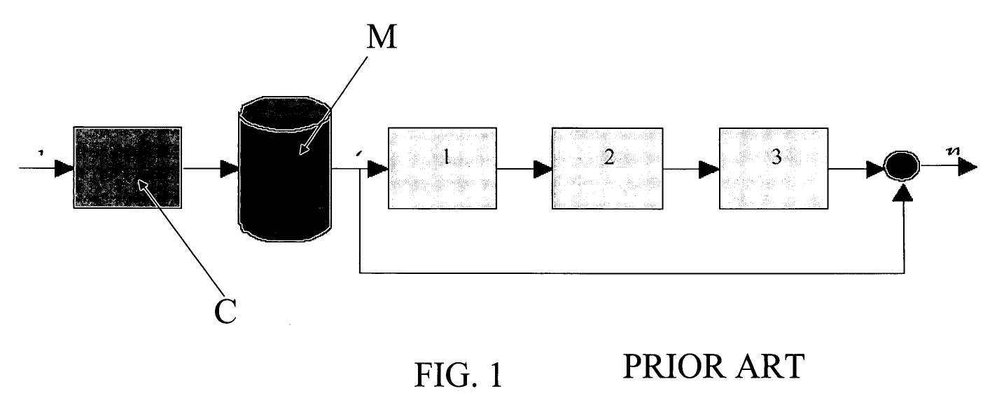

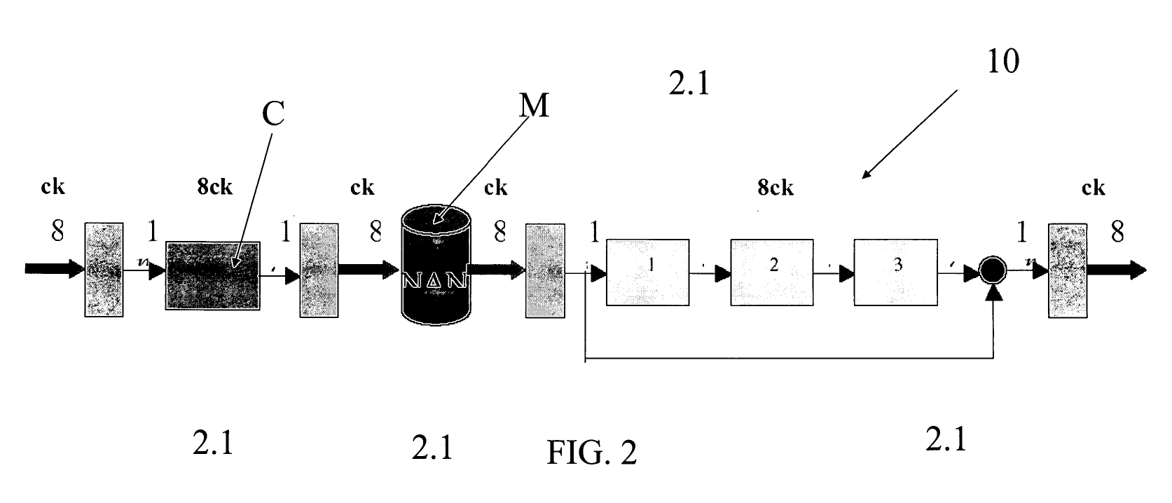

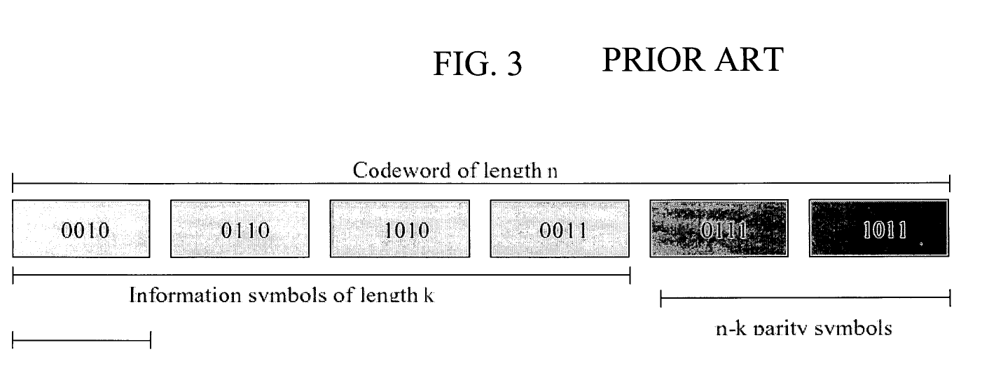

### DETAILED DESCRIPTION

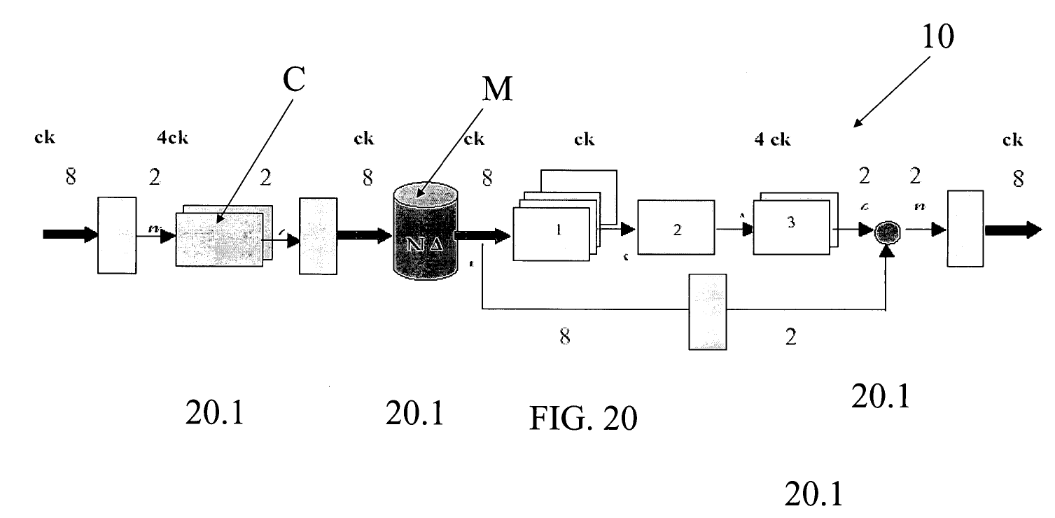

With reference to the figures of the attached drawings, and particularly to the example of FIG. 20, an error correction system realized according to an embodiment of the present invention for information data to be stored in electronic non volatile memory devices, particularly multilevel reading and writing memories, is globally and schematically indicated with 10.

The system 10 comprises a block indicated with C representing the coding step; a block M indicating the electronic memory device and a group of blocks 1, 2 and 3 which are active during the decoding step. In particular, the block 1 is responsible for calculating the so-called code syndrome; the block 2 is a calculation block, while the block 3 is responsible for detecting the error by means of the Chien wrong position search algorithm.

The blocks indicated with 20.1 represent the parallelism conversion blocks on the data flow.

This embodiment of the invention is particularly suitable for the use in a flash EEPROM memory M having a NAND structure; nevertheless nothing prevents this embodiment from also being applied to memories with NOR structure, provided that they are equipped with an error correction system.

Advantageously, the method and system according to this embodiment of the invention is based on an information data processing by means of a BCH code set parallel in the coding step and/or in the decoding step in order to obtain a low latency. The parallelism being used for blocks C, 1 and 3 is selected to optimize the system performance in terms of latency and device area.

Two different methods to make a BCH binary code parallel are provided.

In substance, the parallel scanning can be performed in any phase of the data processing flow according to the application requirements.

The mathematical basics whereon the two parallelization methods of a BCH code according to this embodiment of the invention are based will be described hereafter.

First Parallelization Method:

Coding (Block C) and Syndrome Calculation (Block 1)

The structures for the syndrome coding and calculation are very similar since both involve a polynomial division.

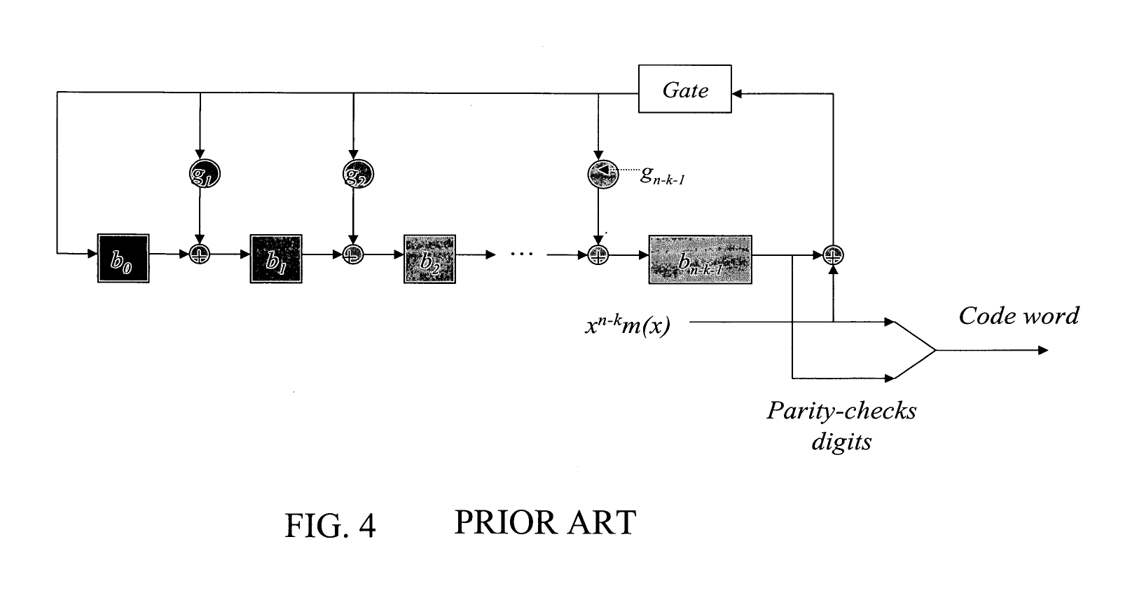

With reference to FIG. 4, the traditional BCH coding structure (prior art) is composed of bᵢ representing memory elements, by adders being simple binary xors and gᵢ can be either 1 or 0, i.e. the dividend coefficients, this means to say that either there is the connection (and consequently the adder) or such a connection does not exist.

The message to be coded enters the circuit performing the division and it simultaneously goes out being so shifted that in the end the coded message is composed of the initial data message and of the parity being calculated in the circuit.

The method intends to parallelize the division calculating the parity of the data to be written in the memory.

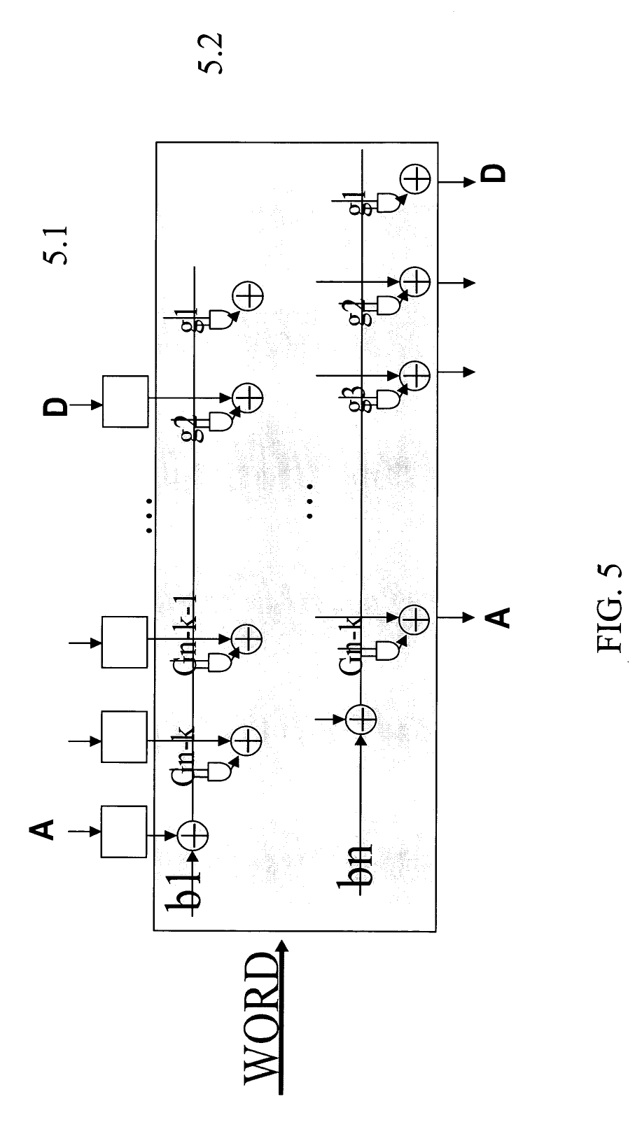

The structure being proposed, in the case of n input data, is represented in FIG. 5.

Registers 5.1 are initially reset. The words to be coded are applied to the logic network 5.2 in succession. After a word has been applied to the logic network 5.2, the outputs of the logic network 5.2 are stored in the registers 5.1. Once the message last word is applied, registers 5.1 will comprise the parity bits to be added to the data message.

It is observed that the number of adders depends on the number one of the code generator polynomial.

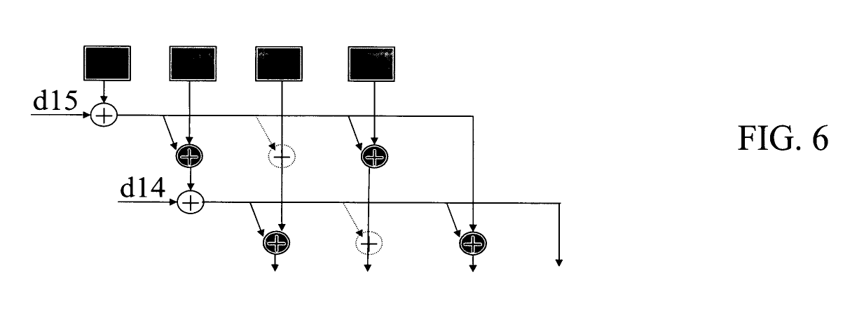

The example of a BCH [15,11] code with generator polynomial g(x)=11011 is to be seen, in the illustrative case of two input data (FIG. 6). Hatched adders are not present since over there g(x) is zero.

The syndrome calculation structure is similar to the coding structure. Each syndrome is calculated by dividing the datum being read from the memory for convenient polynomial factors of the code generator polynomial (prior art) and in the end the register content will be valued at α, α³, α⁵ ed α⁷ by means of a matrix up to obtaining the syndromes. The method being shown for parallelizing the parity calculation can thus be similarly used for the syndrome calculation.

Search for the Error Detection Polynomial Fast BCH.

This block is unchanged with respect to the traditional BCH, but it is observed that, although it is more complex than the decoding algorithm, it is the one requiring less time.

Search for Error Detection Numbers

The syndromes being known, the error detection polynomial is searched, whose roots are the inverse of the wrong positions. This polynomial being known, the roots are then found. This search is performed by means of the Chien algorithm (prior art).

The algorithm carries out a test for all the field elements in order to check if they are the roots of the error detection polynomial.

If αⁱ is a root of the error detection polynomial, then the position n−i is wrong, where n is the code length.

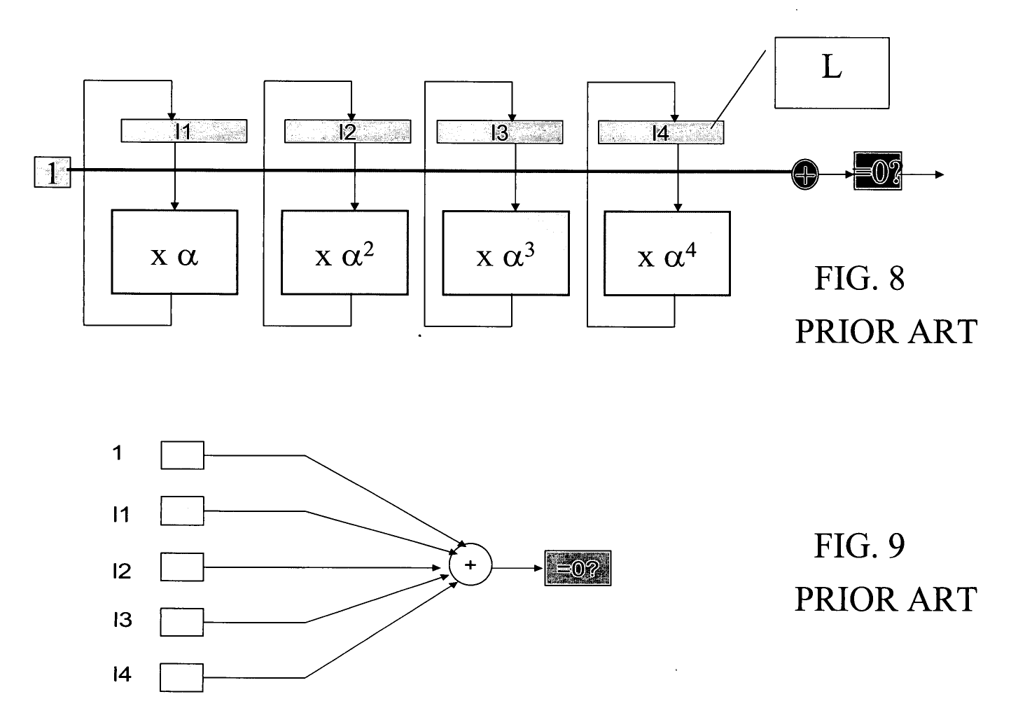

FIG. 8 is a schematic view of this structure, where registers L comprise the error detection polynomial coefficients, they are thus m-bit registers when operation occurs in a field GF(2^{m}) (in the case being taken as an example m=13).

At this point, for each field element, it is determined if this is a root of the error detection polynomial, i.e. to check if the following equation is valid for some j.
1+lₗα^{j}+ . . . +lₜα^{jt}=0
j=0, 1, . . . , n−1

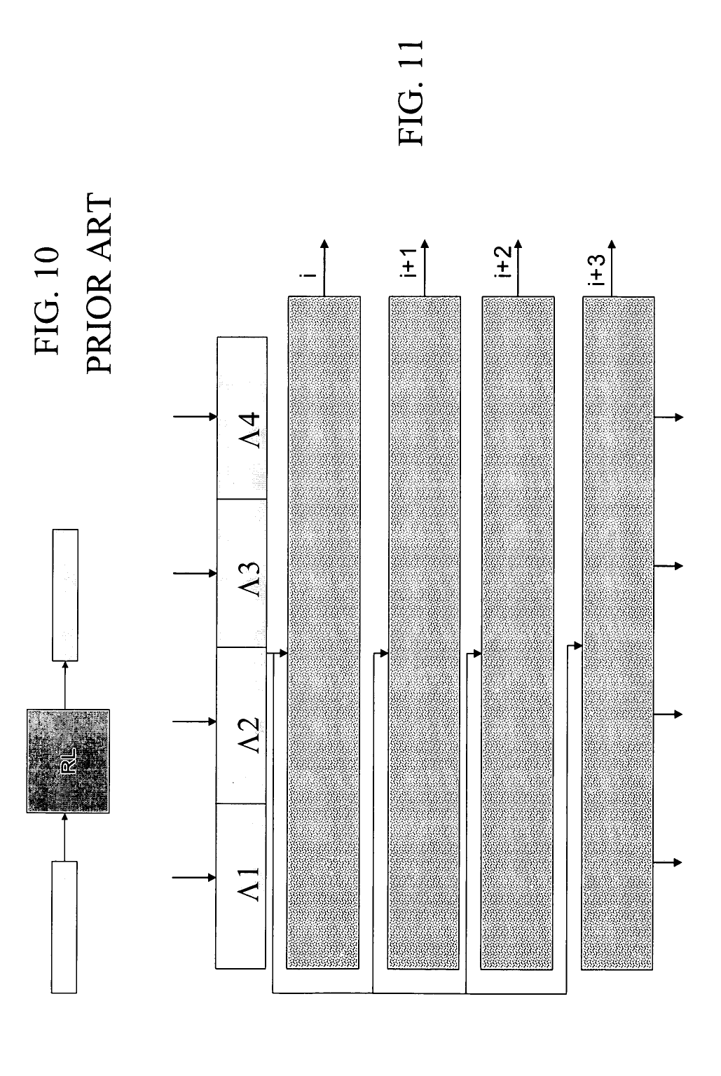

Consequently, a total sum is performed of all the register contents and the field element ‘1’ as shown in FIG. 9. Multiplication blocks (x α, x α², . . .) serve to generate all the field elements and they are performed by means of a logic network being described by means of a matrix whose input is an m-bit vector and whose output is an m-bit vector, as schematically shown in FIG. 10.

With reference to FIG. 11 parallelizing the algorithm means simultaneously carrying out several tests, and consequently checking several wrong positions. Each block represents a test and the content at the end of the last block is carried into the registers containing the error detection polynomial. In the figure case, four tests are simultaneously carried out so that with a single clock stroke it is possible to know if αⁱ, αⁱ⁺¹, αⁱ⁺² or αⁱ⁺³ are the roots of the error detection polynomial.

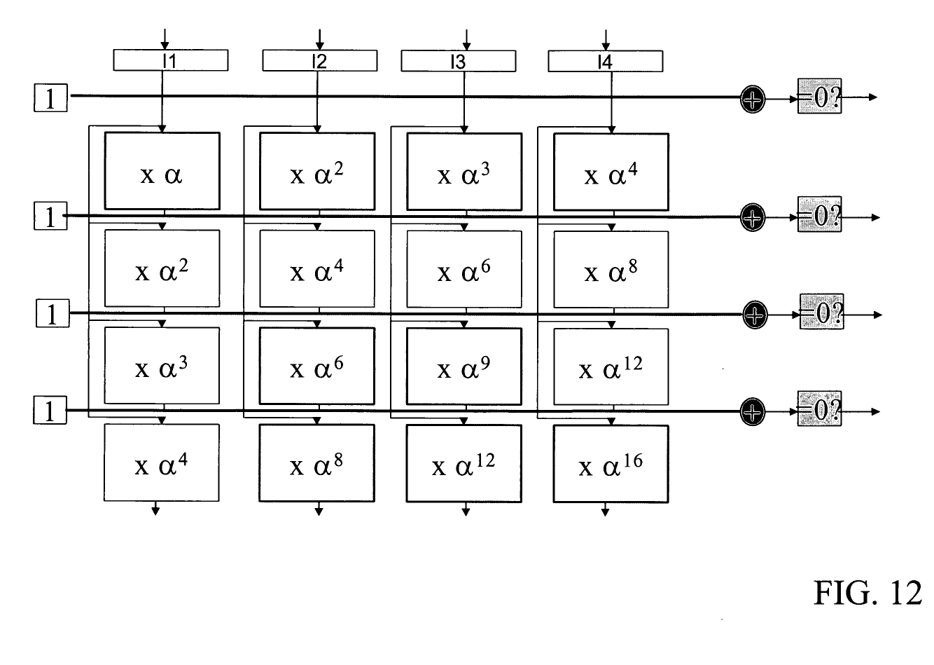

FIG. 12 shows in greater detail the block composition, a four-step parallelism is used, where after every four steps the values return into the registers containing the four lambda coefficients. Also in this case there will be 52 registers (4 registers having 13 bits each).

Second Parallelization Method:

The structure of the system 10 according to a further embodiment of the invention, incorporating coding and decoding blocks, is similar to the structure of an error correction system having a traditional BCH binary code; nevertheless, the internal structure of each block changes.

According to an embodiment of the invention, it is provided to break the initial information message n times and to operate autonomously on each block. The possibility to break the initial information block into two blocks is considered by way of example; there will be thus bits in the even position and bits in the odd position so that two bits enter at a time in the circuit and the speed doubles.

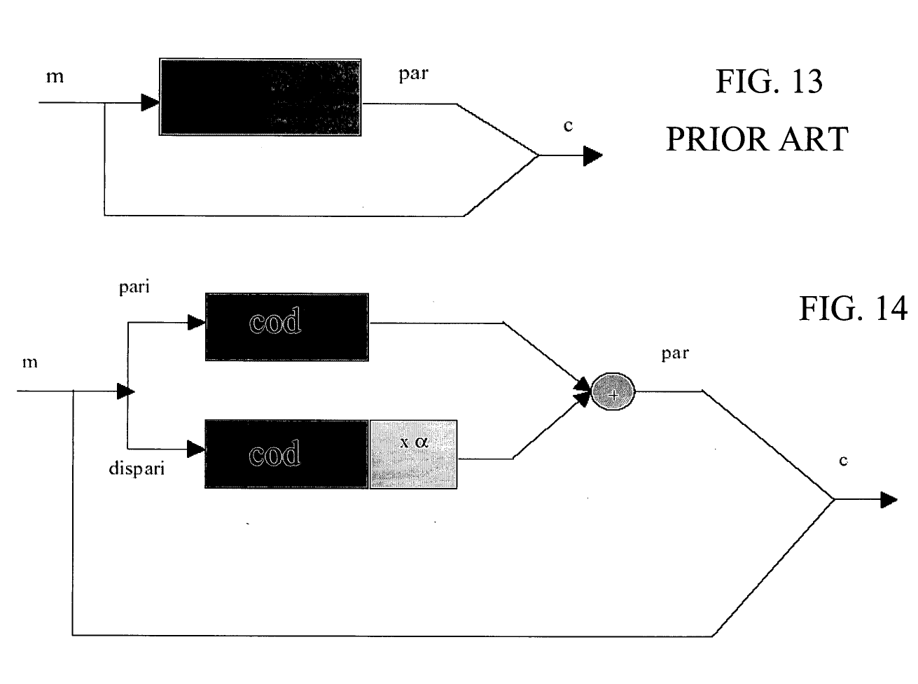

Generally, parity bits are calculated according to the following relation (1), shown in FIG. 13:
par=x^{n-k}m(x)mod g(x) (1)

where m(x) is the data message and g(x) is the code generator polynomial.

Operating in parallel, parity bits par1 and par2 are calculated according to these relations:
par=par1+par2 wherein
par1=[(x^{n-k}m(x))ₚₐᵢᵣ mod g(x)] evaluated in α²
par2=α[(x^{n-k}m(x))ᵢₘₚₐᵢᵣ mod g(x)] evaluated in α^{q} (2)

In a general case of q bits processed in parallel, parity bits par1, par2, . . . , parq are calculated according to these relations:
par=par1+par2+ . . . +parq
par1=[(x^{n-k}m(x))_{qi} mod g(x)]evaluated in α^{q} being

$$i = 0 , … , \frac{n - 1}{q}$$

par2=[α(x^{n-k}m(x))_{qi+1} mod g(x)]evaluated in α^{q} being

$$i = 0 , … , \frac{n - 1}{q}$$

and qi+1<n
. . .
parq=α[(x^{n-k}m(x))_{qi+q-1} mod g(x)]evaluated in α^{ρ}being

$$i = 0 , … , \frac{n - 1}{q}$$

and qi+1<n

An example of known circuit allowing the coding (1) to be realized is shown in FIG. 13.

FIG. 13 thus schematically shows a base block being responsible for calculating the parity by sequentially operating on bits.

On the contrary, for calculating the parity in the double parallelization case the structure of FIG. 14 can be used.

The blocks indicated with “cod” perform both the division as in the traditional algorithm and the evaluation in α². This evaluation can be carried out by means of a logic network being described by a matrix.

As regards odd bits, it is then necessary to multiply the results by α, following the modes being already described.

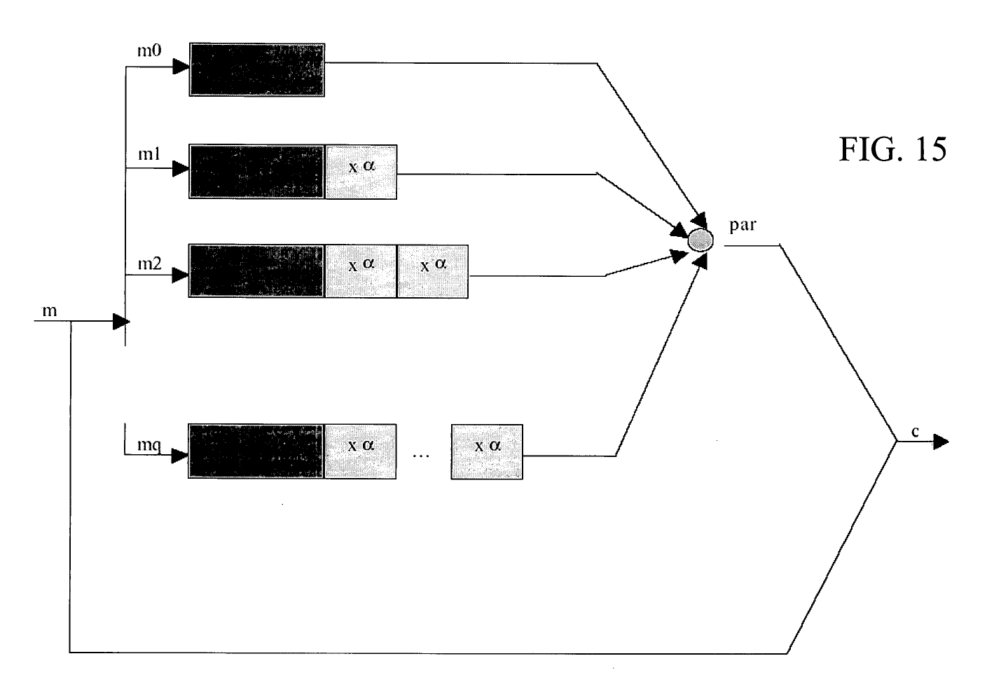

If the circuit is to be further parallelized in a plurality of q blocks, reference can be made to the example of FIG. 15 wherein the outputs of the multiple blocks converge in a single adder node producing the parity.

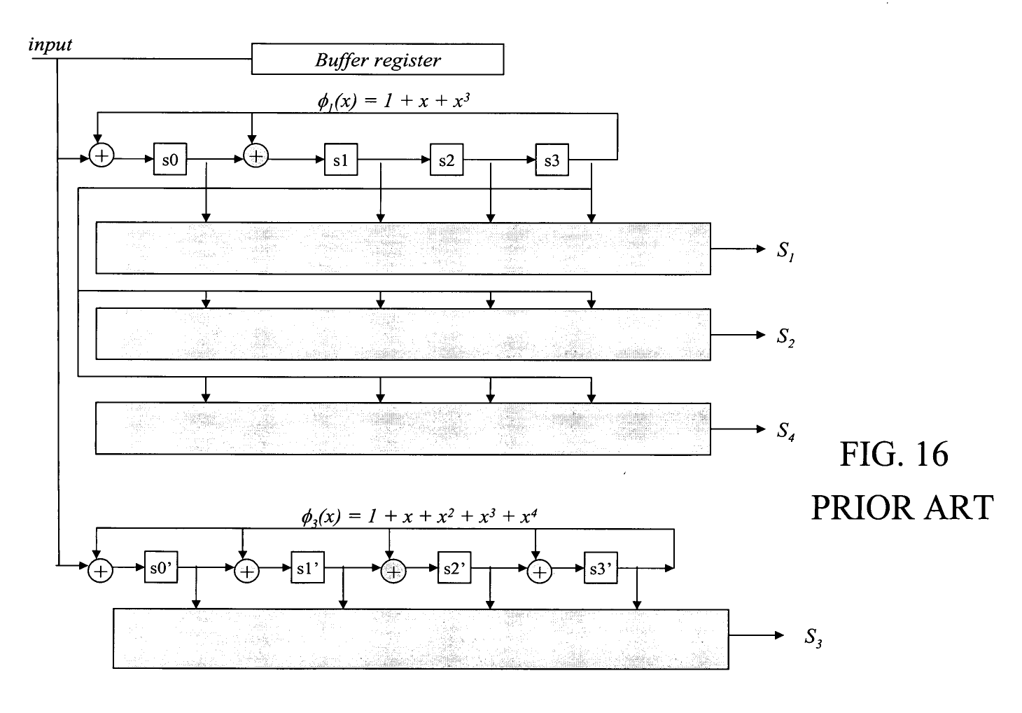

In the case of the traditional serial BCH binary coding it is possible to calculate the so-called code syndromes by means of the following calculation formula (3), corresponding to the circuit block diagram of FIG. 16, in the particular case of a BCH code [15,7]:

$${S}_{j} = {\sum }_{i = 0}^{n - 1} {α}^{ij} {r}_{i} \qquad j = 0 , 1 , … 2 t - 1$$

On the contrary, according to an embodiment of the present invention, the syndrome calculation is set out on the basis of the following formulas (4):
Sⱼ=S1ⱼ+S2 dove:

$$\begin{matrix}{S1}_{j} = {\sum }_{i = 0}^{\frac{n - 1}{2}} {α}^{2 ij} {r}_{2 l} \\ {S2}_{j} = {α}^{j} \times {\sum }_{i = 0}^{\frac{n - 1}{2}} {α}^{2 ij} {r}_{2 l + 1}\end{matrix}$$

A possible implementation of the syndrome calculation according to the prior art is shown in FIG. 16 wherein two errors in a fifteen-long message are supposed to be corrected.

In general terms, advantageously according to an embodiment of the present invention, in a q-bit parallel processing of the syndrome (S1, S2, . . . , Sq), the syndrome calculation is set out on the basis of the following relation:

$${S}_{j} = {\sum }_{i = 0}^{n - 1} {α}^{ij} {r}_{i} \qquad j = 0 , 1 , … 2 t - 1$$

wherein r(x) is an erroneously read word and S1, S2, . . . , Sq are calculated as follows:

$$\begin{matrix}{S}_{j} = {S1}_{j} + {S2}_{j} + … + {Sq}_{j} \\ {S1}_{j} = {\sum }_{l = 0}^{\frac{n - 1}{q}} {α}^{qlj} {r}_{ql} \\ {S2}_{j} = {α}^{j} {\sum }_{l = 0}^{\frac{n - 1}{q}} {α}^{qlj} {r}_{ql + 1} until ql + 1 < n \\ ⋯ \\ {Sq}_{j} = {α}^{( q - 1 ) j} {\sum }_{l = 0}^{\frac{n - 1}{q}} {α}^{qlj} {r}_{ql + q - 1} until ql + q - 1 < n\end{matrix}$$

Consequently, a division is performed similarly to the coding in order to obtain the remainder in the registers marked with s0, s1, . . . . This remainder (seen as a polynomial) must then be valued in α, α², α³, α⁴ as above described, for example by using a logic network being described by matrixes.

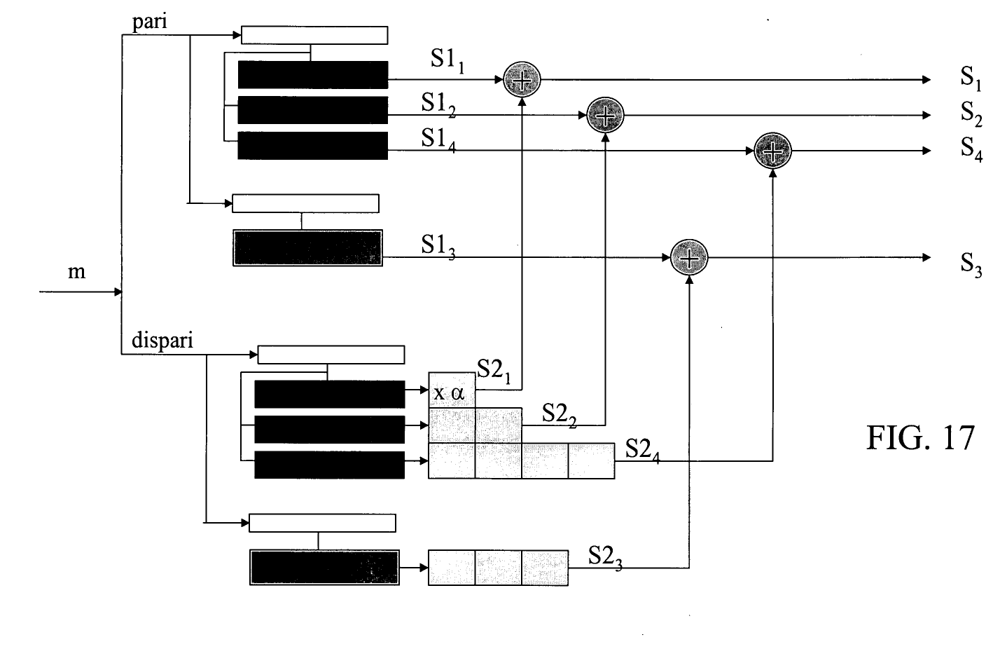

The structure of FIG. 17 represents a simple parallelization obtained for calculating the syndromes for the code taken as an example according to the parallel structure proposed by an embodiment of the present invention and described by the previous formulas.

The blocks shown in FIG. 17 are substantially unchanged with respect to a traditional serial BCH binary coding; nevertheless, it is worth observing that the corresponding decoding algorithm is more complex, but it requires less latency.

In particular, two bits are analyzed simultaneously, the evens and the odds and a structure similar to the traditional syndrome calculation occurs for both.

In fact, both for the evens and for the odds, there is a block calculating the remainder of the division of the input message with a polynomial, a factor of the code generator polynomial.

These remainders must be now valued in precise α powers, but differently from the traditional syndrome calculation, this time they are valued in α², α⁴, α⁶ and in α⁸.

In the case of odd bits, a multiplication for different a powers must be also performed.

The results of the even block and of the odd block will be then added in order to obtain the final syndromes.

Now, according to the prior art, a search algorithm of the roots of the error detection polynomial is located in block 3 and it provides the replacement of all the field elements in the polynomial.

In substance, in the case of a serial BCH code, a test is performed for all the elements of the following field, according to the following formula:
1+lₗα^{j}+ . . . +lₜα^{jt}=0
j=0, 1, . . . , n−1 (5)

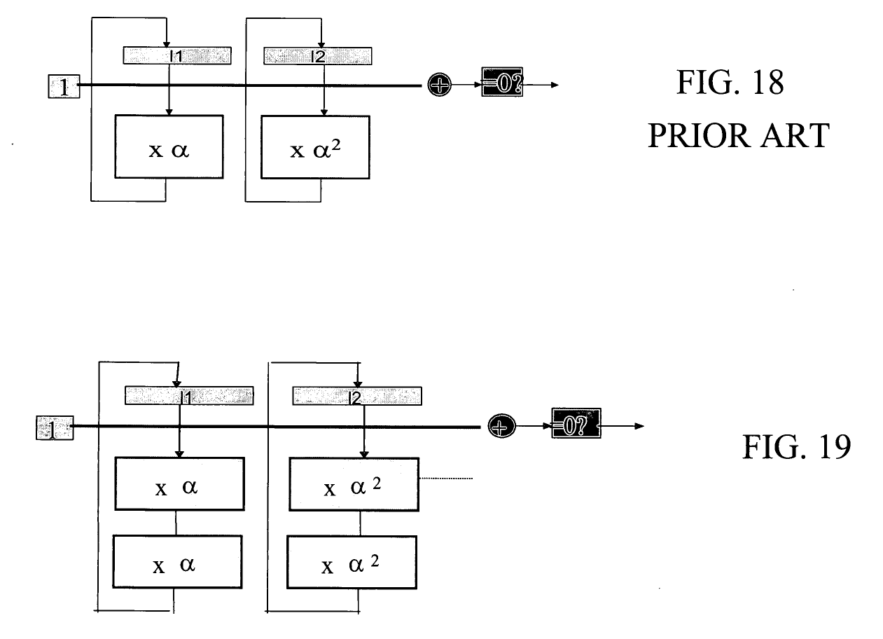

In the traditional serial BCH code, always assuming to correct two errors, a circuit structure like the one of FIG. 18 would be obtained, corresponding to the previous formula (5).

According to an embodiment of the invention, and assuming to parallelize only once, two circuits are obtained, checking each half of the field elements and thus two different tests TEST1 e TEST2:

$$\begin{matrix}\begin{matrix}1 + {l}_{1} {α}^{2 j} + … + {l}_{t} {α}^{2 jt} = 0 & j = 0 , 1 , … , \frac{n - 1}{2}\end{matrix} & TEST 1 ) \\ \begin{matrix}1 + {l}_{1} {α}^{2 j + 1} + … + {l}_{t} {α}^{( 2 j + 1 ) t} = 0 & j = 0 , 1 , … , \frac{n - 1}{2}\end{matrix} & TEST 2 )\end{matrix}$$

Consequently, parallelizing this portion means having several circuits replacing different field elements in the error detection polynomial. In particular, by parallelizing twice the diagram of FIG. 19 is obtained, which is reiterated twice, considering that for the second time registers are initialized by multiplying by α, expressly corresponding to the formulation of the two tests TEST1 e TEST2.

The first circuit performs the first test, i.e. it checks if the field elements being even α powers are the roots of the error detection polynomial, while the second checks if the odd α powers are the roots of the error detection polynomial.

In the general case of a q-bit parallel processing, the search algorithm of the roots of the error detection polynomial is calculated according to the following formula:
1+lₗα^{j}+ . . . +lₜα^{jt}=0
j=0, 1, . . . , n−1

wherein I(x) is the error detection polynomial on which, in the q-bit parallel processing, a plurality of tests (TEST1, TEST2, . . . , TESTq) are performed for all the elements as follows:

$$\begin{matrix}\begin{matrix}1 + {l}_{1} {α}^{qj} + … + {l}_{t} {α}^{qjt} = 0 & j = 0 , 1 , … , \frac{n - 1}{q}\end{matrix} & TEST 1 ) \\ \begin{matrix}1 + {l}_{1} {α}^{qj + 1} + … + {l}_{t} {α}^{( qj + 1 ) t} = 0 & \begin{matrix}j = 0 , 1 , … , \frac{n - 1}{q} \\ being qj + 1 < n\end{matrix} \\ … & \end{matrix} & TEST 2 ) \\ \begin{matrix}1 + {l}_{1} {α}^{qj + q - 1} + … + {l}_{t} {α}^{( qj + q - 1 ) t} = 0 & \begin{matrix}j = 0 , 1 , … , \frac{n - 1}{q} \\ being qj + q - 1 < n\end{matrix}\end{matrix} & TESTq )\end{matrix}$$

The previous description has shown how to realize parallel structures for coding blocks C, syndrome calculation blocks 1 and error correction blocks 3.

It will be proved hereafter how, no correlation existing between the parallelism of one block and the parallelism of another block, it is very advantageous to structure the coding and decoding system 10 architecture in a structure having a hybrid parallelism, and thus a hybrid latency.

Specific reference will be made to the example of FIG. 20 showing a hybrid-parallelism coding and decoding system 11.

The coding and decoding example of FIG. 20 always concerns an application for multilevel NAND structure memory devices.

Assuming an error probability of 10⁻⁵ on a single bit for the NAND memory M, since the protection code operates on a package of 4096 bits, the probability that the package is wrong is 1 out of 50.

In order to understand if the message is correct, the syndrome calculation in block 1 is performed. For this reason for block 1 it is suitable to use a high parallelism in order to reduce the overall average latency.

The Chien circuit (block 3) performing the correction is called on only in case of error (1 out of 50), it is thus suitable, for an area reduction, to use a low-parallelism structure for this single block 3 circuit.

For the coding block C it is possible to choose the most suitable parallelism for the application in order to optimize the coding speed or the overall system area.

This solution allows the coding and decoding time to be reduced by varying the parallelism at will.

Another advantage is given by the fact that the independency of the parallelism of each block being involved in coding and decoding operations allows the performances and the system 10 or 11 area to be optimized according to the applications.

The system 10 of FIG. 20 may be disposed on a memory integrated circuit (IC), which may be part of a larger system such as a computer system.

From the foregoing it will be appreciated that, although specific embodiments of the invention have been described herein for purposes of illustration, various modifications may be made without deviating from the spirit and scope of the invention. Accordingly, the invention is not limited except as by the appended claims.

What is claimed is:

1. A method for correcting errors in read and write non volatile memory electronic devices, particularly flash memories, of the type providing, for the information data to be stored, at least the use of a BCH binary error correction code, providing a processing with a first predetermined parallelism for the coding step, a processing with a second predetermined parallelism for the syndrome calculation and a processing with a third predetermined parallelism for calculating the error position, each parallelism being defined by a respective integer number being independent from the others.

2. The method of claim 1 further providing a parallel polynomial division for the coding and syndrome calculation.

3. The method of claim 1, wherein the integer numbers concerning the first, second and third parallelism are different from each other.

4. A system for correcting errors in read and write non volatile electronic memory devices, particularly flash memories, of the type providing the use of a coding block having a BCH binary correction code and a cascade of decoding blocks wherein a first block is responsible for the code syndrome calculation, a second calculation block and a third block being responsible for the error detection, wherein it comprises a parallel division of at least one of the blocks in the coding and/or decoding step.

5. The system of claim 4, wherein the parallel division provides the parallel multiplication of the structure of a given block and the association of bit composition and decomposition architectures.

6. The system of claim 4, wherein the parallel division concerns coding, syndrome calculation and error detection blocks.

7. The system of claim 4, wherein parity bits in the error correction are calculated according to the following relation:
par=x^{n-k}m(x) mod g(x)
where m(x) is the data message and g(x) is the code generator polynomial and wherein the parallel scanning parity bits (par1, par2, . . . , parq) are calculated according to these relations:
par=par1+par2+ . . . +parq
par1=[(x^{n-k}m(x))_{qi} mod g(x)]evaluated in α^{q} being
$$i = 0 , … , \frac{n - 1}{q}$$
par2=[α(x^{n-k}m(x))_{qi+1} mod g(x)]evaluated in α^{q} being
$$i = 0 , … , \frac{n - 1}{q} and qi + 1 < n$$
. . .
parq=α[(x^{n-k}m(x))_{qi+q-1} mod g(x)]evaluated in α^{ρ}being
$$i = 0 , … , \frac{n - 1}{q}$$
and qi+1<n

8. The system of claim 4, wherein the syndrome calculation is set out on the basis of the following relations:
$${S}_{j} = {\sum }_{i = 0}^{n - 1} {α}^{ij} {r}_{i} \qquad j = 0 , 1 , … 2 t - 1$$
wherein r(x) is an erroneously read word, on which, in a q-bit parallel processing, syndrome bits (S1, S2, . . . , Sq) are calculated according to the following relations:
$$\begin{matrix}{S}_{j} = {S1}_{j} + {S2}_{j} + … + {Sq}_{j} \\ {S1}_{j} = {\sum }_{l = 0}^{\frac{n - 1}{q}} {α}^{qlj} {r}_{ql} \\ {S2}_{j} = {α}^{j} {\sum }_{l = 0}^{\frac{n - 1}{q}} {α}^{qlj} {r}_{ql + 1} until ql + 1 < n \\ ⋯ \\ {Sq}_{j} = {α}^{( q - 1 ) j} {\sum }_{l = 0}^{\frac{n - 1}{q}} {α}^{qlj} {r}_{ql + q - 1} until ql + q - 1 < n\end{matrix}$$

9. The system of claim 4, wherein the search algorithm of the roots of the error detection polynomial is calculated according to the following formula:
1+lₗα^{j}+ . . . +lₜα^{jt}=0
j=0, 1, . . . , n−1
wherein I(x) is the error detection polynomial on which, in a q-bit parallel processing, a plurality of tests (TEST1, TEST2, . . . , TESTq) are performed for all the elements as follows:
$$\begin{matrix}TEST1 ) & 1 + {l}_{1} {α}^{qj} + … + {l}_{t} {α}^{qjt} = 0 & j = 0 , 1 , … , \frac{n - 1}{q} \\ TEST2 ) & 1 + {l}_{1} {α}^{qj + 1} + … + {l}_{t} {α}^{( qj + 1 ) t} = 0 & \begin{matrix}j = 0 , 1 , … , \frac{n - 1}{q} \\ being qj + 1 < n\end{matrix} \\ … & & \\ TESTq ) & 1 + {l}_{1} {α}^{qj + q - 1} + … + {l}_{t} {α}^{( qj + q - 1 ) t} = 0 & \begin{matrix}j = 0 , 1 , … , \frac{n - 1}{q} \\ being qj + q - 1 < n\end{matrix}\end{matrix}$$

10. A method for correcting errors in read and write non volatile memory electronic devices using a BCH binary error correction code for the information data to be stored and comprising the following steps of:
a first predetermined parallelism processing for a coding step;
a second predetermined parallelism processing for a syndrome calculation;
a third predetermined parallelism processing for calculating an error position
wherein each parallelism is defined by a respective integer number being independent from the others.

11. The method of claim 10 further providing a parallel polynomial division for the coding and syndrome calculation steps.

12. The method of claim 10, wherein the integer numbers concerning the first, second and third parallelism are different from each other.

13. A system for correcting errors in read and write non volatile electronic memory devices using of a coding block having a BCH binary correction code and comprising a cascade of decoding blocks wherein:
a first block is responsible for a code syndrome calculation;
a second calculation block and a third block being responsible for the error detection
further comprising a parallel division of at least one of the blocks in a coding and/or decoding step.

14. The system of claim 13, wherein the parallel division provides a parallel multiplication of the structure of a given block and the association of bit composition and decomposition architectures.

15. Thesystem of claim 13, wherein the parallel division concerns coding, syndrome calculation and error detection blocks.

16. The system of claim 13, wherein parity bits in the error correction are calculated according to the following relation:
par=x^{n-k}m(x)mod g(x)
where m(x) is the data message and g(x) is the code generator polynomial and wherein the parallel scanning parity bits (par1, par2, . . . , parq) are calculated according to these relations:
par=par1+par2+ . . . +parq
par1=[(x^{n-k}m(x))_{qi} mod g(x)]evaluated in α^{q} being
$$i = 0 , … , \frac{n - 1}{q}$$
par2=[α(x^{n-k}m(x))_{qi+1} mod g(x)]evaluated in α^{q} being
$$i = 0 , … , \frac{n - 1}{q}$$
and qi+1<n
. . .
parq=α[(x^{n-k}m(x))_{qi+q-1} mod g(x)]evaluated in α^{ρ}being
$$i = 0 , … , \frac{n - 1}{q}$$
and qi+1<n

17. The system of claim 13, wherein the syndrome calculation is set out on the basis of the following relations:
$${S}_{j} = {\sum }_{i = 0}^{n - 1} {α}^{ij} {r}_{i} \qquad j = 0 , 1 , … 2 t - 1$$
wherein r(x) is an erroneously read word, on which, in a q-bit parallel processing, syndrome bits (S1, S2, . . . , Sq) are calculated according to the following relations:
$$\begin{matrix}{S}_{j} = {S1}_{j} + {S2}_{j} + … + {Sq}_{j} \\ {S1}_{j} = {\sum }_{l = 0}^{\frac{n - 1}{q}} {α}^{qlj} {r}_{ql} \\ {S2}_{j} = {α}^{j} {\sum }_{l = 0}^{\frac{n - 1}{q}} {α}^{qlj} {r}_{ql + 1} until ql + 1 < n \\ ⋯ \\ {Sq}_{j} = {α}^{( q - 1 ) j} {\sum }_{l = 0}^{\frac{n - 1}{q}} {α}^{qlj} {r}_{ql + q - 1} until ql + q - 1 < n\end{matrix}$$

18. The system of claim 13, wherein the search algorithm of the roots of the error detection polynomial is calculated according to the following formula:
1+lₗα^{j}+ . . . +lₜα^{jt}=0
j=0, 1, . . . , n−1
wherein I(x) is the error detection polynomial on which, in a q-bit parallel processing, a plurality of tests (TEST1, TEST2, . . . , TESTq) are performed for all the elements as follows:
$$\begin{matrix} TEST 1 ) 1 + {l}_{1} {α}^{qj} + … + {l}_{t} {α}^{qjt} = 0 & j = 0 , 1 , … , \frac{n - 1}{q} & \\ TEST 2 ) 1 + {l}_{1} {α}^{qj + 1} + … + {l}_{t} {α}^{( qj + 1 )} = 0 & j = 0 , 1 , … , \frac{n - 1}{q} & being qj + 1 < n \\ TEST q ) 1 + {l}_{1} {α}^{qj + q - 1} + … + {l}_{t} {α}^{( qj + q - 1 ) t} = 0 & j = 0 , 1 , … , \frac{n - 1}{q} & being qj + q - 1 < n\end{matrix}$$

19. A method, comprising:
coding according to a BCH algorithm a block of data that includes groups of multiple data bits by sequentially operating on each group and simultaneously operating on the bits within each group; and
storing the coded block of data in a memory.

20. The method of claim 19 wherein each group includes the same number of data bits.

21. The method of claim 19 wherein the memory comprises a multi-level memory.

22. A method, comprising:
retrieving from a memory a block of coded data that includes groups of multiple data bits; and
calculating a syndrome of the block of coded data according to a BCH algorithm by sequentially operating on each group of data bits and simultaneously operating on the bits within each group.

23. The method of claim 22 wherein each group includes the same number of data bits.

24. The method of claim 22 wherein the memory comprises a multi-level memory.

25. The method of claim 22, further comprising:
wherein the syndrome includes syndrome groups of multiple data bits; and
detecting an error within the block of coded data according to the BCH algorithm by sequentially operating on each syndrome group of data bits and simultaneously operating on the bits within each syndrome group.

26. A method, comprising:
retrieving from a memory a block of coded data;
calculating a syndrome of the block of coded data according to a BCH algorithm, the syndrome including groups of multiple data bits; and
detecting an error within the block of coded data according to the BCH algorithm by sequentially operating on each group of data bits and simultaneously operating on the bits within each group.

27. A system, comprising:
a memory; and
a calculation circuit coupled to the memory and operable to,
code, according to a BCH algorithm, a block of data that includes groups of multiple data bits by sequentially operating on each group and simultaneously operating on the bits within each group,
store the coded block of data in the memory.

28. A system, comprising:
a memory operable to store a block of coded data that includes groups of multiple data bits; and
a calculation circuit coupled to the memory and operable to calculate a syndrome of the block of coded data according to a BCH algorithm by sequentially operating on each group of data bits and simultaneously operating on the bits within each group.

29. The system of claim 28 wherein:
the syndrome includes syndrome groups of multiple data bits; and
the calculation circuit is further operable to detect an error within the block of coded data according to the BCH algorithm by sequentially operating on each syndrome group of data bits and simultaneously operating on the bits within each syndrome group.

30. A system, comprising:
a memory operable to store a block of coded data; and
a calculation circuit operable to,
calculate a syndrome of the block of coded data according to a BCH algorithm, the syndrome including groups of multiple data bits, and
detect an error within the block of coded data according to the BCH algorithm by sequentially operating on each group of data bits and simultaneously operating on the bits within each group.
